(19) United States
(12) Patent Application Publication
(10) Pub. No.: US 2011/0050036 A1
(43) Pub. Date: Mar. 3, 2011

(54) Bias Circuit for Electric Field Transducers

(76) Inventor: Stephen S. Gilardi, Mystic, CT (US)

(21) Appl. No.: 12/874,916

(22) Filed: Sep. 2, 2010

Related U.S. Application Data
(60) Provisional application No. 61/239,658, filed on Sep. 3, 2009.

(51) Int. Cl. H01L 41/09

(52) U.S. Cl. 310/317

(57) ABSTRACT

A circuit includes an AC voltage driver configured to output an AC voltage having a given shape and given one or more frequency components. An electric field type transducer is provided including a positive voltage terminal and a negative voltage terminal. A capacitor is connected between the AC voltage driver and the positive voltage terminal of the transducer. A diode is connected across the two terminals of the electric field type transducer. The diode operates on the signal applied by the AC voltage driver so that a substantially only positive AC voltage is applied to the positive voltage terminal of the transducer. In addition, the applied positive AC voltage applied to the positive voltage terminal of the transducer has an applied shape and applied one or more frequency components that are substantially the same as the given shape and the given one or more frequency components.

### RELATED APPLICATION DATA

Priority is hereby claimed to provisional application No. 61/239,658, filed Sep. 3, 2009, the content of which is hereby expressly incorporated herein in its entirety.

### COPYRIGHT NOTICE

This patent document contains information subject to copyright protection. The copyright owner has no objection to the facsimile reproduction by anyone of the patent document or the patent, as it appears in the US Patent and Trademark Office files or records, but otherwise reserves all copyright rights whatsoever.

### FIELD OF THE DISCLOSURE

The present disclosure relates to circuitry and circuit components for preventing unwanted reverse bias in electric field type transducers, such as ceramic transducers or piezoelectric transducers or polymer film transducers (ferroelectric transducers) or capacitive transducers.

### BACKGROUND OF THE DISCLOSURE

Voltage signals are applied to electric field type transducers in order to impart and transmit the voltage signals in the form of vibrations at frequencies that may range from infrasonic to ultrasonic. More specifically, these types of transducers (e.g. projectors, transmitters, or actuators) convert an applied electric voltage to an electric field in the transducer's dialectic material, and then convert that electric field to mechanical displacement. Among these electric field type transducers, dielectric type transducers require that a DC bias be supplied from a DC voltage source separate from the input voltage signal to be transmitted. Meanwhile, a large class of ferroelectric type transducers have had their dielectric material “poled”, a process whereby the ceramic material is polarized to create in it a permanent electric field. It is important that, in deployment, the transducer not be reversed biased, i.e., not receive a significant negative voltage value at its positive input. Yet there is a risk that this might happen if the peak-to-peak input voltage level exceeds a certain level or if a reverse biased input voltage signal is mistakenly applied to the transducer. Serious damage to the transducer may result.

### BRIEF DESCRIPTION OF THE DRAWINGS

FIG. 1 is a block diagram of a background art transducer circuit.

FIG. 2 is a block diagram of a transducer circuit in accordance with one embodiment.

FIG. 3 is a schematic diagram of a transducer circuit in accordance with another embodiment.

FIG. 4 is a schematic diagram of a transducer circuit in accordance with another embodiment.

FIG. 5 is a waveform diagram.

### DETAILED DESCRIPTION

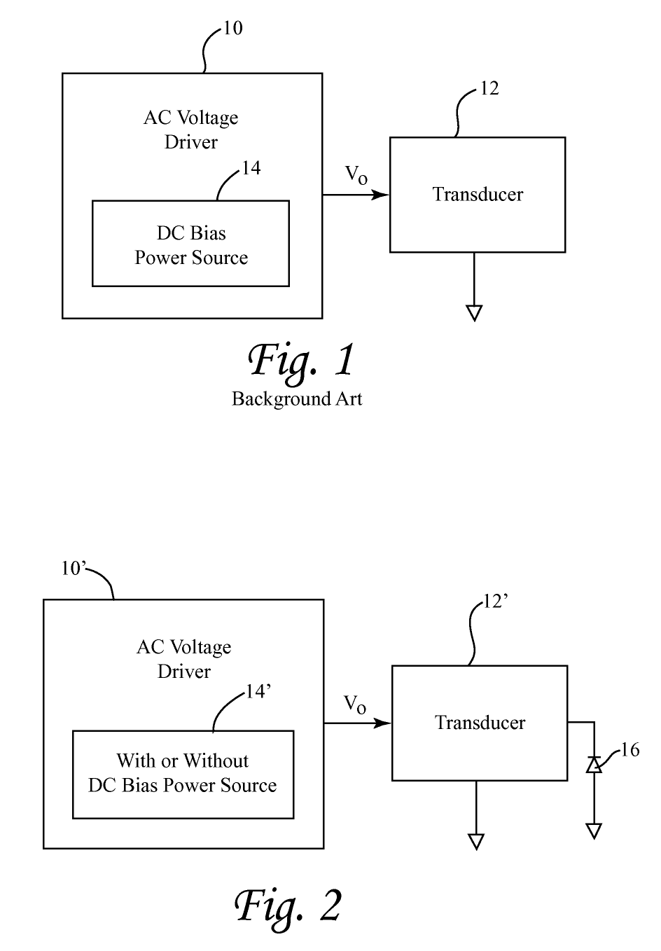

FIG. 1 is a simplified block diagram of a driven transducer system, including AC voltage driver circuitry 10 and an electric field type transducer 12 (ceramic or capacitive or polymer film). The illustrated AC voltage driver circuitry 10 includes circuitry providing a remote (from the transducer) DC bias power source 14, which may include a blocking capacitor and a blocking resistor. The illustrated transducer 12 may include at least one electric field type transducer, located at the end of a transmission cable driven by an AC voltage from the remote AC driver circuitry 10 simultaneously driven by a DC voltage, from remote DC bias power source 14. The AC voltage driver may include an AC power amplifier driven by a pulsed AC drive signal. The pulsed AC drive signal may be powered by, for example, 60 Hz AC prime power. A pulsed drive signal may be sent to the power amplifier at some drive signal frequency. The AC power amplifier may include a voltage-source power amplifier, and a DC bias blocking capacitor may be provided between the output of the voltage-source power amplifier and the transmission cable connected to transducer 12.

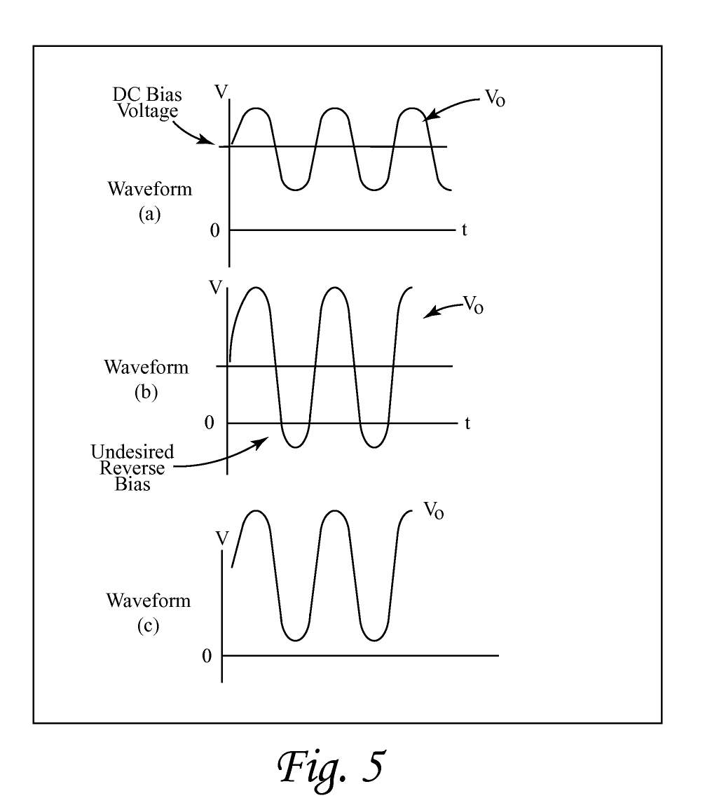

By way of example referring to the background circuit shown in FIG. 1, the AC power amplifier (not shown) and the transducer 12 may each be grounded. The ground connection indicated in all descriptions and Figures, may or may not refer to conventional earth grounding. The voltage Vₒ of the signal input to transducer 12 is the output of AC voltage driver circuit 10. This voltage may be represented by the waveform (a) shown in FIG. 5, when the level of the AC voltage input by AC voltage driver 10 is in a normal range. As shown, the output voltage Vₒ oscillates about a DC bias voltage, and stays entirely above the zero voltage level. If the AC voltage provided by AC voltage driver 10 has an excessive peak-to-peak voltage, an undesired reverse bias is formed as shown in waveform (b) in FIG. 5. In this case, the DC bias voltage is not high enough to prevent the oscillating AC voltage Vₒ from becoming a negative voltage value.

One embodiment of circuitry of this disclosure is shown in FIG. 2. The illustrated circuit includes an AC voltage driver 10′ and a transducer 12′. The illustrated AC voltage driver 10′ may or may not include a DC bias power source 14′. At least one blocking capacitor is provided as part of AC voltage driver circuit 10′. The illustrated AC voltage driver circuit 10′ outputs an output voltage Vₒ, which is input typically via a transmission line, to a positive terminal of transducer 12′. The negative terminal of transducer 12′ is connected to ground. In the illustrated embodiment, the cathode of a diode 16 is connected to the positive terminal of transducer 12′, and the anode of diode 16 is connected to ground.

With or without a DC bias power source 14′ (including a blocking capacitor), the resulting output waveform Vₒ across transducer 12′ in the circuit of FIG. 2 will be as shown in waveform (c) in FIG. 5. This will be the case, generally, regardless of the peak-to-peak amplitude of voltage Vₒ applied to transducer 12′ by AC voltage driver 10′.

The AC drive signal voltage Vₒ may be of a number of different signal formats, for example, single or multiple pulsed sine waves, AM, FM, PM modulated continuous sine waves, or pulsed or continuous pseudorandom noise. By providing diode 16 in the circuit illustrated in FIG. 2, a DC bias voltage with an amplitude automatically self-adjusting is added to voltage Vₒ, thereby precluding the applied AC drive signal from approaching a voltage value that goes below a given level, generally zero volts or a small number of volts below zero volts. The diode 16 also prevents reverse-biasing of the transducer 12′ even if a negative DC bias were to be mistakenly applied.

This results in the prevention of an unwanted reverse biasing of transducer 12′, and (optionally) eliminates the need for a DC bias power source. While AC voltage driver circuit 10′ may have a DC bias power source 14′, a separate and costly (in terms of hardware components and ongoing power consumption) DC power source is not necessary. In addition, the need for an AC signal blocking resistor can be eliminated. In addition, the required level of peak voltage rating of the amplified voltage sent to the transducer cable can be reduced.

The circuitry illustrated in FIG. 2 replaces the equipment and methods found in other circuits for electric field type transducer DC biasing, which, for example, may use a stand-alone, high voltage, DC power supply, adding a settable voltage amplitude and a settable voltage polarity, to produce the correct high voltage DC bias required by electric field type transducers for a proper operation. Conventional circuits, for example, as shown in FIG. 1, may also include the use of a high voltage, high capacitance DC bias voltage blocking capacitor (not specifically shown in FIG. 1) and a high resistance DC bias voltage blocking resistor (not specifically shown in FIG. 1).

The circuit shown in FIG. 2 can provide a fail-safe protection function by eliminating the possibility of transducer damage, for example, if the transducer is an electric field type transducer, which could be caused by the inadvertent application of a high-voltage DC bias voltage having an incorrect polarity.

In addition, the circuitry as shown in FIG. 2 can eliminate the possibility of transducer damage and/or improper transducer operation, due to the application of a DC bias voltage of proper polarity, but having a DC bias voltage amplitude which is too small for safe and proper (first quadrant) transducer operation. The described improper combination of levels of DC bias and AC drive voltage can cause the electric field within the ceramic to alternate from a high-level positive value to a moderate-to-high-level negative value, at the signal frequency. These bipolar field alternations can cause heating and destruction of an electric field type transducer.

Another benefit of the circuitry shown in FIG. 2 is that it can eliminate the requirement for an AC blocking resistor, having a high resistance and a high voltage rating. Such resistors are required in certain existing transducer bias configurations, that use a separate DC bias voltage power supply.

The circuitry shown in FIG. 2 can also allow a required high-voltage DC blocking capacitor to be located at the same location as the transducer, rather than being located remotely from the transducer near the power amplifier. This would present an advantage over existing circuits which typically provide a DC blocking capacitor and a stand-alone high voltage DC bias voltage power supply which must be located remotely from the transducer.

The circuitry shown in FIG. 2 also can eliminate the need, found in conventional circuits, to transmit a high voltage DC bias voltage superimposed with a high voltage AC drive signal. The circuit disclosed herein requires a transmission of only an AC drive voltage, through a power-amplifier-to-transducer transmission cable. This can cause a fifty percent (50%) reduction of the transition cable's peak-voltage rating requirement, between conductors of the amplifier to the transducer transmission cable.

Another advantage of the circuitry shown, for example, in FIG. 2, is that a high-voltage step-up transformer can be co-located near its associated (for example) in-water transducer, without adding a high voltage conductor to the transmission cable. A conventional approach includes transmitting a DC bias voltage through a transmission cable, to a series blocking resistor, and a DC blocking capacitor, to the secondary of a transformer co-located with a transducer which would require an additional high-voltage-rated conductor in the transmission cable.

The circuitry shown, for example, in FIG. 2, can further enable the use of low-voltage transmission cable, in conjunction with a transducer or multiple series-connected or parallel connected transducers, with one or more co-located step-up high-voltage transformers. The circuitry disclosed herein may produce a required DC bias at the location of the transducer itself, without requiring a separate and additional high-voltage-rated transmission cable conductor.

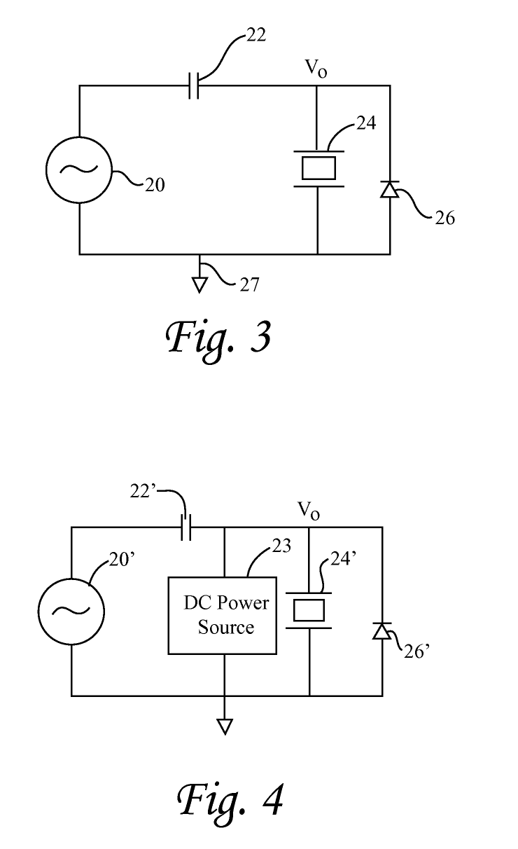

FIG. 3 shows a circuit in accordance with an alternate embodiment of the present disclosure. The illustrated circuit includes an AC power source 20, a blocking capacitor 22, a transducer 24, and a diode 26. AC power source 20 is connected between ground 27 and blocking capacitor 22. The AC power source 20 generates an output voltage Vₒ at an output side of blocking capacitor 22, which is applied across transducer 24. Diode 26 is connected across transducer 24.

In accordance with another embodiment of the disclosure, in FIG. 4, an AC driven transducer circuit is provided, which includes an AC power source 20′, a blocking capacitor 22′, a DC power source 23, a transducer 24′, and a diode 26′. DC power source 23 applies a DC bias voltage across transducer 24′, to protect, at least partially, against undesired reverse biasing of the voltage across transducer 24′. Such a DC power source is not provided in the embodiment shown in FIG. 3.

In each of the embodiments shown in FIGS. 3 and 4, the provision of a diode 26 or 26′ provides a number of advantages, including preventing the reverse biasing of the transducer 24 or 24′. The diode provided across the transducers in the various embodiments herein may, for example, be a NTE517 silicon high voltage plastic rectifier for industrial and microwave oven use, for example, as provided by Electronics, Inc. at 44 Farrand St., Bloomfield, N.J. 07003. This example of diode includes controlled avalanche characteristics combined with the ability to dissipate reverse power. It includes a low forward voltage drop. The typical reverse leakage current is less than 0.1 micro amps, and the diode includes a high overload surge capacity.

Diode 26′ may be any semiconductor or other device that has certain characteristics like a diode, such that the shape of the waveform applied by the AC voltage driver remains substantially intact. For this application as shown in FIG. 4, the diode has: a sufficiently high reverse breakdown voltage to prevent a reverse over-voltage destruction of the diode due to peak signal voltage plus DC bias voltage; a sufficiently high surge current rating to allow the first cycles of current applied to the blocking capacitor to dissipate to a reasonable range—consistent with the continuous current rating of the diode; and a reverse leakage current that is sufficiently low to not discharge the capacitor.

In the embodiment shown in FIG. 4, in contrast to conventional circuits, a DC bias blocking resistor between the output of capacitor 22′ and the positive terminal of DC power source 23 is not necessary. Typically, a large impedance resistor is placed at this location in conventional circuits.

The high impedance resistor that might be provided between capacitor and the positive terminal of DC power source 23 can keep the DC power source from shorting the AC source, and also allow the AC current or most of the AC current to go to the transducer 24′.

In applications involving sonar, the peak voltage of the AC source can be thousands of volts.

While voltage source type drivers are depicted in the above-described embodiments, current source type drivers may be utilized instead.

The claims as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

What is claimed is:

1. Apparatus comprising:
an AC driver configured to output an electrical signal of varying amplitude, having given one or more signal integrity components;
a transducer set of electric field type transducers, the set including at least one positive voltage terminal and at least one negative voltage terminal;
a capacitor connected between the AC driver and the at least one positive voltage terminal; and
a diode connected at one end to the at least one positive voltage terminal and at another end to the at least one negative voltage terminal;
wherein the diode operates on the electrical signal applied by the AC driver so that a substantially only positive AC voltage is applied to the at least one positive voltage terminal of the transducer, thereby preserving the given one or more signal integrity components.

2. The apparatus according to claim 1, wherein the AC driver includes a voltage source type driver.

3. The apparatus according to claim 1, wherein the AC driver includes a current source type driver.

4. The apparatus according to claim 1, wherein the electrical signal output by the AC driver includes a voltage level of varying amplitude.

5. The apparatus according to claim 1, wherein the electrical signal output by the AC driver has a given shape.

6. The apparatus according to claim 5, wherein the electrical signal output by the AC driver has given one or more frequency components.

7. The apparatus according to claim 1, wherein the electrical signal output by the AC driver has given one or more frequency components.

8. The apparatus according to claim 1, wherein the transducer set includes one electric field type transducer.

9. The apparatus according to claim 1, wherein the transducer set includes plural electric field type transducers connected in series or in parallel.

10. The apparatus according to claim 6, wherein the positive AC voltage applied to the at least one positive voltage terminal of the transducer set has an applied shape and applied one or more frequency components that are substantially the same as the given shape and the given one or more frequency components.

11. Apparatus comprising:
an AC voltage driver configured to output an AC voltage having a given shape and given one or more frequency components;
an electric field type transducer including a positive voltage terminal and a negative voltage terminal;
a capacitor connected between the AC voltage driver and the positive voltage terminal of the transducer; and
a diode connected across the two terminals of the electric field type transducer;
wherein the diode operates on the electrical signal applied by the AC voltage driver so that a substantially only positive AC voltage is applied to the positive voltage terminal of the transducer.

12. The apparatus according to claim 11, wherein the applied positive AC voltage applied to the positive voltage terminal of the transducer has an applied shape and applied one or more frequency components that are substantially the same as the given shape and the given one or more frequency components.

13. A method comprising:
outputting at a given terminal an electric signal of varying amplitude, having given one or more signal integrity components;
providing a transducer set of electric field type transducers, the set including at least one positive voltage terminal and at least one negative voltage terminal;
providing a capacitor connected between the given terminal and the at least one positive voltage terminal; and
connecting a diode at one end to the at least one positive voltage terminal and at another end to the at least one negative voltage terminal;
wherein the diode operates on the electrical signal applied to the AC driver so that a substantially only positive AC voltage is applied to the at least one positive voltage terminal of the transducer set, thereby preserving the given one or more signal integrity components.
